(19) United States
(12) Patent Application Publication
(10) Pub. No.: US 2026/0235664 A1
(43) Pub. Date: Aug. 13, 2026

(54) IC Testing Control

(71) Applicant: Mellanox Technologies, Ltd., Yokneam (IL)

(72) Inventors: Alex Weiss, Tirat Carmel (IL); Avi Levi, Adi (IL); Joseph Haim, Netanya (IL)

(21) Appl. No.: 19/049,020

(22) Filed: Feb. 10, 2025

(51) Int. Cl. G01R 31/28

(52) U.S. Cl. CPC G01R 31/2877; G01R 31/2875

(57) ABSTRACT

A testing temperature control system includes a Controlled-Temperature Device (CTD) Temperature Sensor, a Device Under Test (DUT)-Temperature Control Circuit, and a CTD Temperature Control Circuit. The CTD Temperature Sensor is to send CTD-temperature data indicative of a temperature of a CTD in which the DUT is mounted. The DUT-Temperature Control Circuit is to send a temperature control signal responsively to DUT-temperature data, the DUT temperature data being received from the DUT and indicative of a temperature of the DUT. The CTD Temperature Control Circuit is to control the temperature of the CTD responsively to the temperature control signal and to the CTD-temperature data.

### TECHNICAL FIELD

The present disclosure relates to the testing of integrated circuits (ICs) and, particularly, to Device-Under-Test (DUT) control.

### BACKGROUND

Testing of Integrated Circuits (ICs) is a crucial step in semiconductor manufacturing and quality assurance. ICs operate in various environments where fluctuations can affect their performance. In particular, IC datasheets specify an operational temperature range, typically classified as:
Commercial: 0° C. to 70° C.
Industrial: −40° C. to 85° C.
Automotive/Military: −55° C. to 125° C. or higher

An Environmental IC test system typically includes a controlled-temperature environment (e.g., a temperature chamber); the tested IC (Device Under Test, or DUT) is placed in the controlled-temperature environment. The environmental temperature is set to a specified value, and then an automatic text is performed. This may repeat for several preset temperature values, as defined by the test procedure.

### General Description

An embodiment that is described herein provides a testing temperature control system including a Controlled-Temperature Device (CTD) Temperature Sensor, a Device Under Test (DUT)-Temperature Circuit, Control and a CTD Temperature Control Circuit. The CTD Temperature Sensor is to send CTD-temperature data indicative of a temperature of a CTD in which the DUT is mounted. The DUT-Temperature Control Circuit is to send a temperature control signal responsively to DUT-temperature data, the DUT temperature data being received from the DUT and indicative of a temperature of the DUT. The CTD Temperature Control Circuit is to control the temperature of the CTD responsively to the temperature control signal and to the CTD-temperature data.

In a disclosed embodiment, the CTD Temperature Control Circuit is to control the temperature of the CTD responsively to a preset Proportional-Integral-Derivative (PID) function. In an example embodiment, the DUT-Temperature Control Circuit is to send the temperature control signal responsively to a Process Value (PV) temperature setting input.

In some embodiments, the DUT is to send the DUT-temperature data over a shared bus, and the testing temperature control system further includes arbitration circuitry to arbitrate the shared bus between the DUT-temperature data and testing control data. In an example embodiment, the shared bus is an Inter-Integrated-Circuit (I2C) bus.

In a disclosed embodiment, the DUT includes a communication switch. In another embodiment, the DUT includes a communication transceiver. In yet another embodiment, the system further includes a thermocouple device to send the CTD-temperature data.

There is additionally provided, in accordance with an embodiment that is described herein, a testing temperature control system including a temperature setting device, a temperature control circuit, and arbitration circuitry. The temperature setting device is to set a temperature of a Device Under Test (DUT). The temperature control circuit is to receive from the DUT, over a shared bus, DUT-temperature data indicative of the temperature of the DUT as measured by the DUT, and to control the temperature setting device responsively to the DUT-temperature data. The arbitration circuitry is to arbitrate the shared bus between the DUT-temperature data and testing control data.

There is also provided, in accordance with an embodiment that is described herein, a method for controlling a temperature of a Device-Under-Test (DUT). The method includes, using a Controlled-Temperature Device (CTD) Temperature Sensor, sending CTD-temperature data indicative of a temperature of a CTD in which the DUT is mounted. Using a DUT-Temperature Control Circuit, a temperature control signal is sent responsively to DUT-temperature data, the DUT temperature data being received from the DUT and indicative of a temperature of the DUT. Using a CTD Temperature Control Circuit, the temperature of the CTD is controlled responsively to the temperature control signal and to the CTD-temperature data.

The present disclosure will be more fully understood from the following detailed description of the embodiments thereof, taken together with the drawings in which:

### BRIEF DESCRIPTION OF THE DRAWINGS

FIG. 1 is a block diagram that schematically illustrates a Testing System, in accordance with an embodiment that is disclosed herein;

FIG. 2 is a control diagram that schematically illustrates the temperature-control structure of a testing system, in accordance with an embodiment that is disclosed herein;

FIG. 3 is a flowchart that schematically illustrates a method for temperature control in a testing system, in accordance with an embodiment that is disclosed herein;

FIG. 4A is a block diagram that schematically illustrates a testing system that arbitrates between a plurality of serial buses, in accordance with an embodiment that is disclosed herein;

FIG. 4B is a block diagram that schematically illustrates a testing system that comprises a single DUT Temperature Control Circuit, in accordance with an embodiment that is disclosed herein;

FIG. 5 is a timing diagram that schematically illustrates the waveforms of a test temperature cycle in a testing system, in accordance with an embodiment that is disclosed herein;

FIG. 6 is a block diagram that schematically illustrates an IC Test System, in accordance with an embodiment that is disclosed herein;

FIGS. 7A and 7B are, respectively, a 3-D view and a block diagram of a data center architecture, in accordance with an embodiment that is disclosed herein;

FIG. 7C is a block diagram that schematically illustrates an inter-transceiver communication system, in accordance with an embodiment that is disclosed herein;

FIG. 8 is a block diagram that schematically illustrates a computer system, in accordance with an embodiment that is disclosed herein;

FIGS. 9A and 9B illustrate a top view and perspective view, respectively, of a transceiver module operatively coupled to a network adapter, in accordance with an embodiment disclosed herein;

FIG. 10 depicts exemplary scenarios for use of an optical a transceiver, in accordance with an embodiment disclosed herein; and

FIG. 11 is a block diagram that schematically illustrates a computing system, in accordance with an embodiment disclosed herein.

### DETAILED DESCRIPTION OF EMBODIMENTS

### Overview

The testing of electronic devices under preset temperatures is a crucial process in ensuring their reliability, performance, and durability. This testing evaluates how devices behave when exposed to specific temperature ranges, simulating real-world operating conditions. It helps identify potential failures caused by thermal stress and ensures that the devices meet industry standards and function reliably throughout their lifecycle.

While commercial off-the-shelf temperature controllers may set and maintain the desired environmental temperature, the actual temperature of the Device Under Test (DUT) may differ for various reasons, including, for example:
1. PCB Mounting Effects: The DUT's thermal behavior changes when mounted on a printed circuit board (PCB), affecting heat dissipation.
2. Self-Heating: The DUT generates heat during operation, raising its internal temperature beyond the set environmental temperature.
3. Thermal Gradients: Differences in heat distribution can occur due to component placement, air circulation, and thermal resistance.
4. Others.

According to the present disclosure, an IC Testing System comprises a temperature controller, referred to hereinbelow as a Controlled Temperature Device (CTD). The DUT (typically an IC die) is mounted on a test circuit (typically a Printed Circuit Board (PCB)) within the CTD. An on-die temperature sensor sends a die-temperature indication to an additional controller, which sends an indication to a Proportional-Integral-Derivative (PID) controller in the CTD; the PID controller then controls the CTD temperature so that the die will reach the desired temperature. The die-temperature indication enables to obtain accurate result within specific temperature during environmental cycle testing and to calibrate the DUT in real temperature condition. From the ‘die side’, this internal temperature feedback is required to: reach stability.

It should be noted that the techniques to be described below with reference to testing temperature control can be used, in alternative embodiments, for the control of other testing and industrial parameters, such as pressure, motor-speed, liquid flow rate, etc.

Embodiments that are disclosed herein provide for apparatuses and methods that accurately and rapidly set the DUT temperature to a preset value (referred to as Set Point, or SP). The disclosed techniques are able to maintain the DUT temperature at the preset value with high accuracy, even when the power consumption of the DUT (and, thus, its self-heating) changes over time during testing.

In an embodiment, a Testing System comprises a temperature controller (referred to a Controlled Temperature Device, or CTD, below) that comprises a CTD Temperature Sensor and a Heating-Cooling device, is used. The DUT comprises a DUT Temperature Sensor that sends DUT temperature indications to a DUT Temperature Control Circuit (e.g., a Microcontroller Unit (MCU) that is programmed accordingly). The DUT Temperature Control Circuit compares the SP to the DUT temperature indication, and sends a correction signal to the CTD, which modifies its temperature accordingly.

In an embodiment, the DUT comprises a serial bus that is used for communication with a processor and/or with a test-equipment, and, also for outputting DUT temperature indications.

In another aspect of the disclosure, an arbiter circuitry is added to a serial bus (e.g., I2C) that connects a PC to the tester. The arbiter allows sharing of a serial bus by two types of transactions-temperature data sent from the DUT die to the additional controller, and PC-tester communication. The Testing System comprises an arbitration circuitry that arbitrates the DUT bus between the processor and/or the test equipment and the DUT Temperature Control Circuit.

### System Description

Integrated Circuits (ICS) are sometimes tested at preset temperatures. A testing cycle may comprise a plurality of tests that are done sequentially at preset temperatures. Each test may comprise running one or more test programs that cause additional DUT internal heating (due to power dissipation). As a result, during the testing period the temperature of the DUT varies. In some cases, a complete set of tests runs uninterrupted after the DUT temperature stabilizes at a first test temperature (e.g., 0°), and then the same (or a different) set of tests runs after the DUT stabilizes at a second test temperature (e.g., 70°), and so on.

The setting of the temperature typically involves heating or cooling of an environment (the CTD), measuring the temperature and using a control feedback loop to stabilize testing and industrial parameters, such as pressure, motor-speed, liquid flow rate, or the temperature at a specified value.

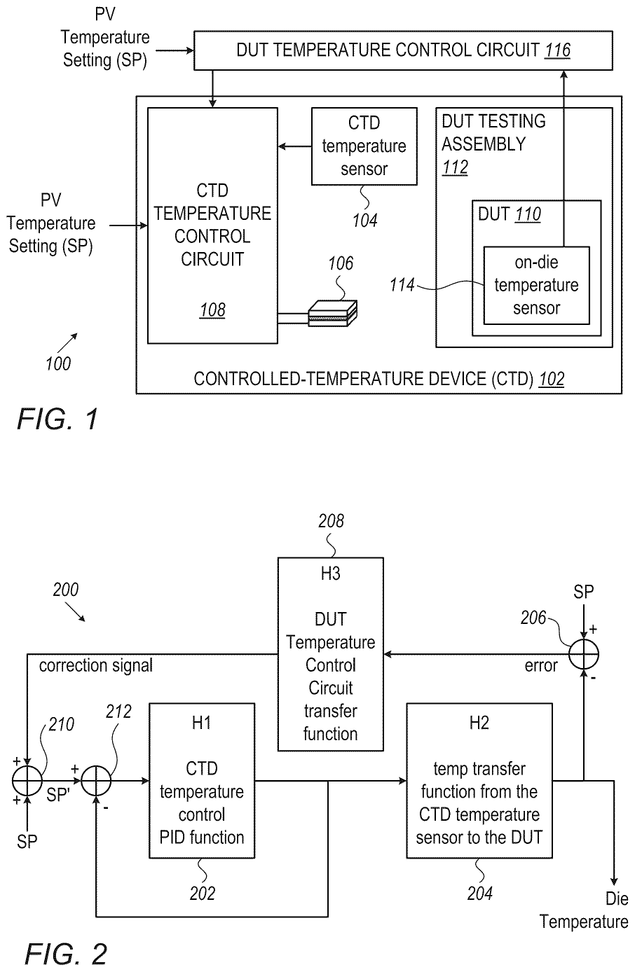

FIG. 1 is a block diagram that schematically illustrates a Testing System 100, in accordance with an embodiment that is disclosed herein. Test System 100 comprises a Controlled-Temperature Device (CTD) 102 that may heat or cool according to a preset temperature. The CTD includes a CTD Temperature-Sensor 104 that sends CTD-temperature data according to the measured CTD temperature, a Heating/Cooling device (e.g., a Peltier element) 106, and a CTD Temperature Control Circuit 108, that is configured to set the CTD temperature. The CTD Temperature Control Circuit 108 implements a control loop that sets the CTD Temperature measured by the CTD Temperature-Sensor 104 to the preset temperature, typically using a PID algorithm. The control loop uses an independent feedback system increasing the accuracy of the measurement.

In an embodiment, CTD Temperature-Sensor 104 may comprise a Thermocouple device; in other embodiments, other types of thermal sensors may be used, including, for example, Negative Temperature Coefficient (NTC) Thermistors, Resistance Temperature Detectors (RTDs), Semiconductor-Based Sensors, and others.

A Device Under-Test (DUT) 110 is placed in a DUT Testing Assembly 112 within the CTD (the DUT Testing Assembly may comprise, for example, a Printed Circuit Board (PCB), with a Zero-Insertion-Force (ZIF) socket for the DUT).

Since the CTD Temperature-Sensor may be remote from the DUT, the temperature in the DUT may be different from the temperature measured by the CTD Temperature-Sensor, and, hence, the DUT temperature may be set erroneously. According to the example embodiment illustrated in FIG. 1, DUT 110 comprises an on-die DUT Temperature Sensor 114 that measures the temperature of the DUT and sends a DUT temperature indication to a DUT-Temperature Control Circuit 116, which receives a Process Value (PV) Temperature Setting, and sends a temperature control signal, responsively to the PV Temperature Setting and to the DUT-temperature data, to the CTD Temperature Control Circuit 108. (In some embodiments, Temperature Control Circuit 116 comprises a Micro-Controller Unit (MCU).).

As explained above, the CTD Temperature Control Circuit 108 implements a control loop that sets the CTD Temperature measured by the CTD Temperature-Sensor 104 to the PV set point. To correct for the difference between the DUT temperature and the temperature measured by the CTD Temperature-Sensor, the CTD Temperature Control Circuit 108 changes the PV set point according to the temperature control signal, (which is, therefore, also referred to as a Correction Signal). Thus, the CTD Temperature Control Circuit will set the CTD temperature to the corrected PV set point, and any DUT temperature error (e.g., the difference between the DUT temperature and the PV set point) will be mitigated. Thus, by properly setting the preset value, the user (e.g., a test engineer) can run test sets according to a predefined set of testing temperatures; the die temperature will stabilize to each preset value before the test is run.

In some embodiments, CTD Temperature Control Circuit 108 further comprises safety mechanisms that prevent overheating and override the PID function if the measured temperature exceeds a preset safety limit.

The configuration of Testing System 100 illustrated in FIG. 1 and described herein above is cited by way of example. Other configurations may be used in alternative embodiments. For example, in some embodiments, DUT Testing Assembly 112 is mounted in a Testing Chamber; in embodiments, more than one DUT may be tested concurrently, and the DUT Temperature Control Circuit 116 comprises an input multiplexer, to control the temperature of one selected DUT at a time.

FIG. 2 is a control diagram that schematically illustrates the temperature-control structure of a testing system 200, in accordance with an embodiment that is disclosed herein.

In terms of temperature-control functions, the testing system 200 comprises:
1. An H1 Control Function 202, which describes the output to input ratio of CTD Temperature Control Circuit 100 (FIG. 1). In embodiments, H1 may be a PID function, described in the frequency domain, as:

$${H}_{1} ( s ) = {K}_{p} + {K}_{i} * \frac{1}{S} + {K}_{d} * s ,$$

and, in the time domain, the output u (t) as a function of the input e (t):

$$u ( t ) = {K}_{p} e ( t ) + {K}_{i} {\int }_{0}^{t} e ( τ ) d τ + {K}_{d} \frac{dr ( t )}{dt}$$

2. An H2 Control Function 204, which describes the transfer function of the heat propagation from the CTD Temperature Sensor 104 to the DUT 110 (FIG. 1). In embodiments, H2 may comprise, for example, a delay function.
3. An Error Subtractor 206, which subtracts the DUT temperature (measured by DUT Temperature Sensor 114, FIG. 1) from the PV set point (referred to, in the context of FIG. 2, as SP), to get an Error signal.
4. An H3 Control Function 208, which describes the transfer function of the DUT Control Function. The output of H3 is referred to as a correction signal that corrects the set temperature according to the actual die temperature. In embodiment, H3 is defined so as to achieve fast and accurate convergence of the DUT Temperature according to the PV temperature point (SP).
5. An SP-Correction Adder 210, which adds the correction signal to the SP value, to form a corrected SP, designated SP′.
6. A Subtractor 212 for closing the temperature control loop; the Subtractor subtracts the output of H1 from the SP′; the result of the subtraction is input to H1.
   By suitable setting of H1 parameters and the function of H3, the DUT temperature can follow SP accurately, overcoming injected errors, with fast response time and with controlled overshoots/undershoots.

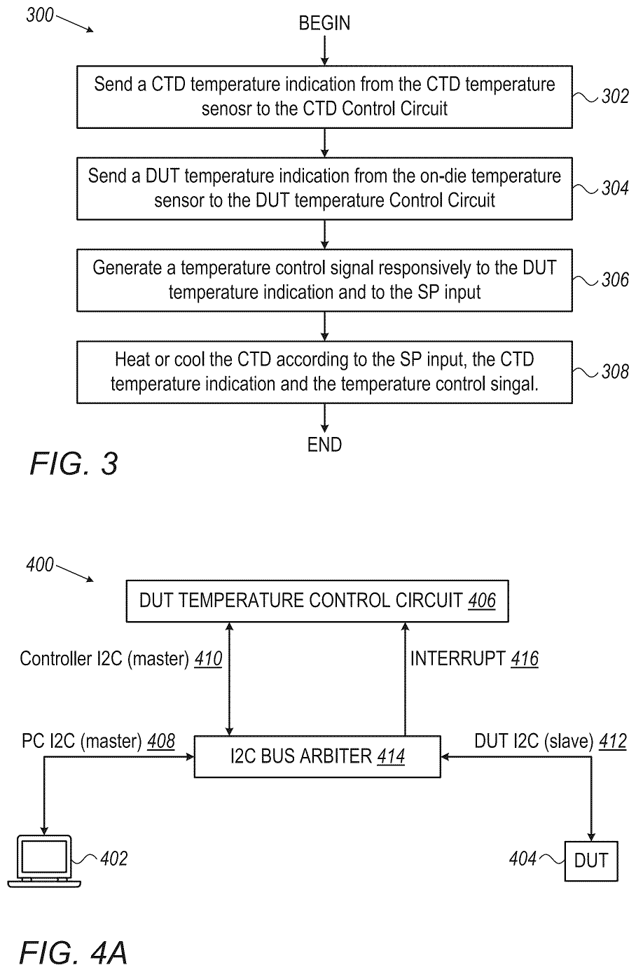

FIG. 3 is a flowchart 300 that schematically illustrates a method for temperature control in a testing system, in accordance with an embodiment that is disclosed herein. The flowchart is executed by the various elements of Test System 100 (FIG. 1), including CTD 102, CTD Temperature-Sensor 104, Heating/Cooling device 106, CTD Temperature Control Circuit 108, DUT 110, DUT temperature sensor 114 and DUT-Temperature Control Circuit 116.

The flowchart begins at a Send-CTD-Temperature-Indication operation 302, wherein the CTD Temperature Sensor sends an indication to the CTD Control Circuit, according to the measured CTD temperature. In some embodiments the indication may be an analog signal, indicative of the temperature; in other embodiments the signal may be digital, comprising a digital representation of the measure temperature.

Next, at a Send-DUT-Temperature-Indication operation 304, the DUT temperature sensor sends an indication to the DUT Temperature Control Circuit according to the DUT temperature (e.g., generated by the DUT temperature sensor). In some embodiments, the indication may comprise a digital signal that is sent on a serial bus (e.g., Inter-Integrated-Circuit, (I2C)).

Now, at a Generate-Temperature-Control Signal operation 306, the DUT Temperature Control Circuit generates a temperature control signal (also referred to as a Correction Signal) according to the DUT temperature indication, and to the present SP input.

Lastly at a Heat-or-Cool operation 308, the CTD heats or cools, typically by activating the Heating/Cooling device 106 (FIG. 1), according to the SP input, the correction signal, and the CTD temperature indication.

After operation 308 the flowchart ends.

### Operation Over a Shared Bus

In some embodiments, the DUT communicates with a processor during testing, for example, for test setup and for test management. In other embodiments, the test is governed by an Automatic-Test-Equipment (ATE) that communicates with the DUT. In an embodiment to be described below, the communication is done over a serial bus, such as Inter-Integrated-Circuit (I2C).

In some embodiments, the DUT Temperature Sensor 114 sends the DUT-temperature data to the DUT-Temperature Control Circuit 116 over the same serial bus and, hence, bus arbitration may be needed.

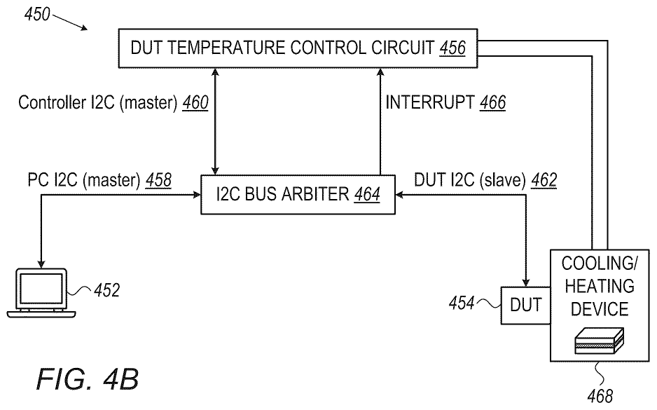

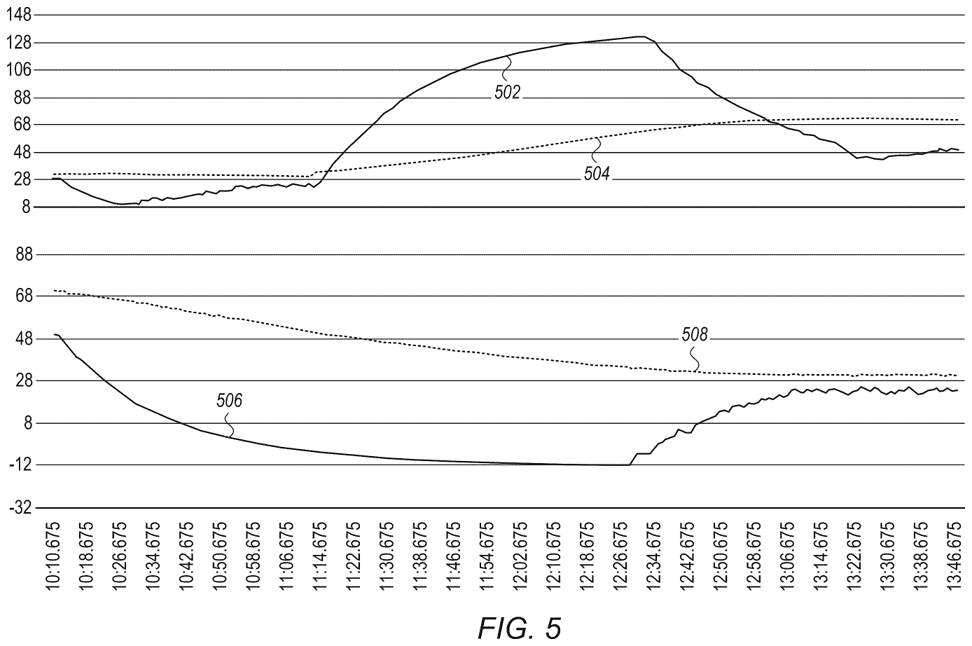

FIG. 4A is a block diagram that schematically illustrates a testing system 400 that arbitrates between a plurality of serial buses, in accordance with an embodiment that is disclosed herein. A personal computer (PC) 402 communicates with a DUT 404 (in embodiments, DUT 404 may be similar or identical to DUT 110, FIG. 1). The DUT 404 sends DUT Temperature Indications to a DUT Temperature Control Circuit 406 (similar or identical to DUT Temperature Control Circuit 116, FIG. 1).

According to the example embodiment illustrated in FIG. 4A, PC 402 is an I2C Master, and communicates serial packets over a PC I2C bus 408; DUT Temperature Control Circuit 406 is also an I2C master, communicating serial packets over a Controller I2C bus 410. The DUT 404, however, is an I2C Slave, communicating over and IC bus 412. (In alternative embodiments, PC 402 may comprise any type of computing device; for example, a microcontroller, or a connection to a remote computer.)

Testing system 400 further comprises an arbitration circuitry 414 that arbitrates between requests to connect to the DUT I2C Bus 412, emanating from PC 410 and from DUT Temperature Control Circuit 406. In various embodiments, the Bus Arbiter 414 will arbitrate according to a preset policy, which may include, for example:
1. always prioritize the PC requests;
2. always prioritize the controller requests;
3. Use a rotating priority scheme.

In an embodiment, the I2C Bus Arbiter 414 is configured to remember unserved Temperature Control Circuit requests and, when the PC releases the bus, send a signal to the Temperature Control Circuit over an Interrupt wire 416, indicating that the Temperature Control Circuit can now access the DUT.

The configuration of testing system 400, illustrated in FIG. 4A and described herein above is cited by way of example. Other configurations may be used in alternative embodiments. For example, in some embodiments, DUT 404 comprises a separate serial bus for temperature indications, and no arbitration is needed. In some embodiments, other serial buses are used, such as Serial Processor Interface (SPI), Universal Synchronous Bus (USB), and other serial and parallel buses. In embodiments, other types of computers may be used in leu of PC 402; In an embodiment, PC 402 is replaced by an Automatic Test Equipment (ATE).

In some embodiments, a single temperature controller is used.

FIG. 4B is a block diagram that schematically illustrates a testing system 450 that comprises a single DUT Temperature Control Circuit, in accordance with an embodiment that is disclosed herein.

Testing system 450 comprises a testing computer 452, a DUT 454 that comprises an on-die temperature sensor (not shown), and a single DUT Temperature Control Circuit 456. In some embodiments, DUT Temperature Control Circuit 456 may comprise a PID controller, that receives a temperature indication from the on-die temperature sensor, runs a PID control function and drives a temperature setting device (in the present example a cooling/heating device 468) to set the on-die temperature according to a preset value.

Testing system 450 further comprises buses 458, 460 and 412, and an interrupt indication 456, which are similar in functionality to the respective 408, 410, 412 buses and to the 416 interrupt indication that were described above, with reference to FIG. 4A.

FIG. 5 is a timing diagram 500 that schematically illustrates the waveforms of a test temperature cycle in a testing system, in accordance with an embodiment that is disclosed herein. A Waveform 502 and a Waveform 504 show the temperature indications sent, respectively, by the CTD Temperature Sensor and by the DUT temperature sensor, during a 30° to 70° heating cycle. Similarly, A Waveform 506 and a Waveform 508 show the temperature that the CTD Temperature Sensor and the DUT temperature sensor send (respectively), during a 70° to 30° cooling cycle.

The CTD temperature waveforms show that the CTD overshoots and undershoots considerably, while the DUT temperature waveforms show smooth convergence to the target temperatures.

It should be noted that the waveforms illustrated in FIG. 5 were obtained by a particular set of H1, H2 and H3 function parameters. In embodiments, other sets of parameters may be used, e.g., for faster convergence (allowing a limited amount of overshoot).

The configurations of Testing Systems 100, 200, 400, the Control Diagram 200, the timing diagram 500 and the method of flowcharts 300, illustrated in FIGS. 1 through 5 and described hereinabove, are example configurations, timing diagrams, control diagrams and methods that are shown purely for the sake of conceptual clarity. Any other suitable configurations and methods can be used in alternative embodiments. The different elements of Testing Systems 100, 200 and 400, and any components thereof, may be implemented in an integrated circuit, such as an application specific integrated circuit (ASIC) or a field-programmable gate-array (FPGA). Alternatively, some elements of CTD Temperature Control Circuit 108 and DUT Temperature Control Circuit 116 may be implemented in software, or in combination of software and hardware elements.

### Use Examples

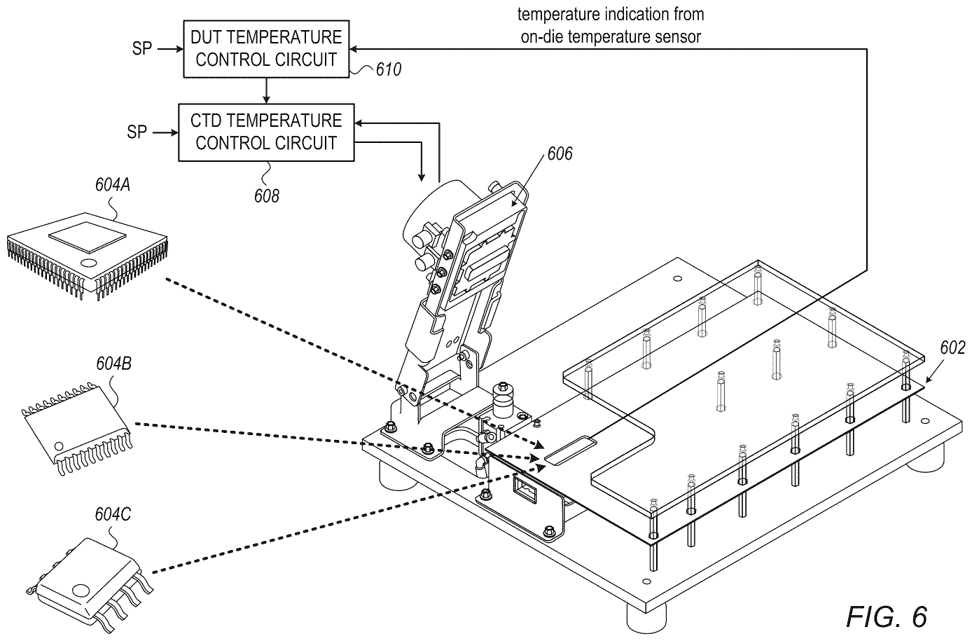

FIG. 6 is a block diagram that schematically illustrates an IC Test System 600, in accordance with an embodiment that is disclosed herein.

A Printed-Circuit Board (PCB) 602 comprises testing circuitry and a socket (e.g., a Zero-Insertion-Force (ZIF) socket for mounting a Device Under Test (DUT). According to the example embodiment illustrated in FIG. 6, the DUT may comprise a Communication Switch 604A, a Communication Transceiver 604B, or any other suitable IC 604C.

A CTD 606 is mounted on a hinge, operable to thermally couple CTD 606 to the package of the DUT 604A, 604B or 604C. Thus, the temperature of the CTD closely matched the temperature of the DUT package.

A CTD Temperature Control circuit 608 is configured to receive temperature indication from the CTD 606, and to heat or cool the CTD. A DUT Temperature Control Circuit 610 receives a DUT temperature indication from an on-die temperature sensor and sends a temperature error indication to the CTD Temperature Control Circuit 608. Thus, the DUT die temperature can be set to a given Set-Point (SP).

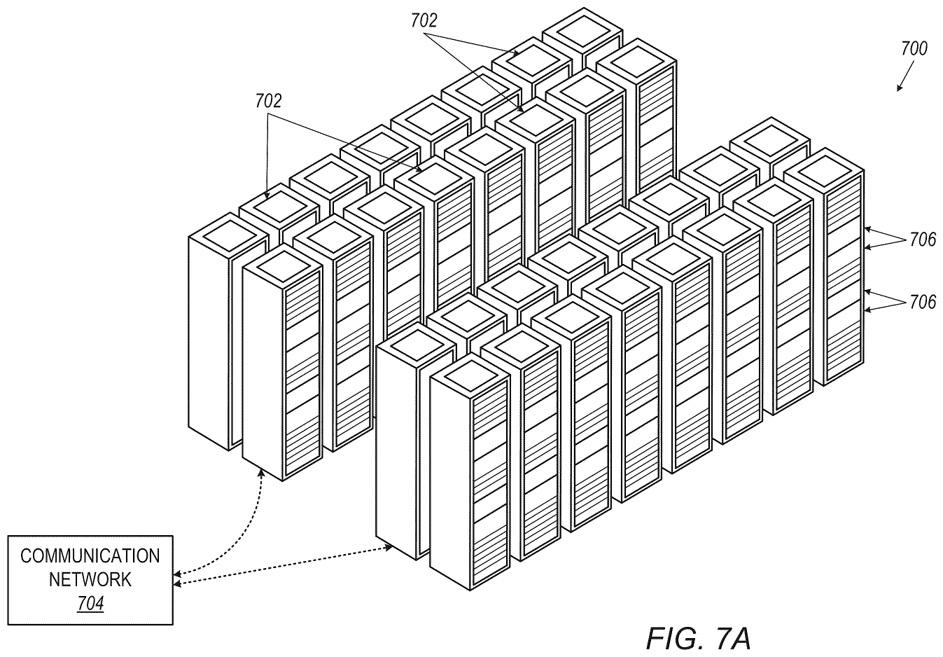

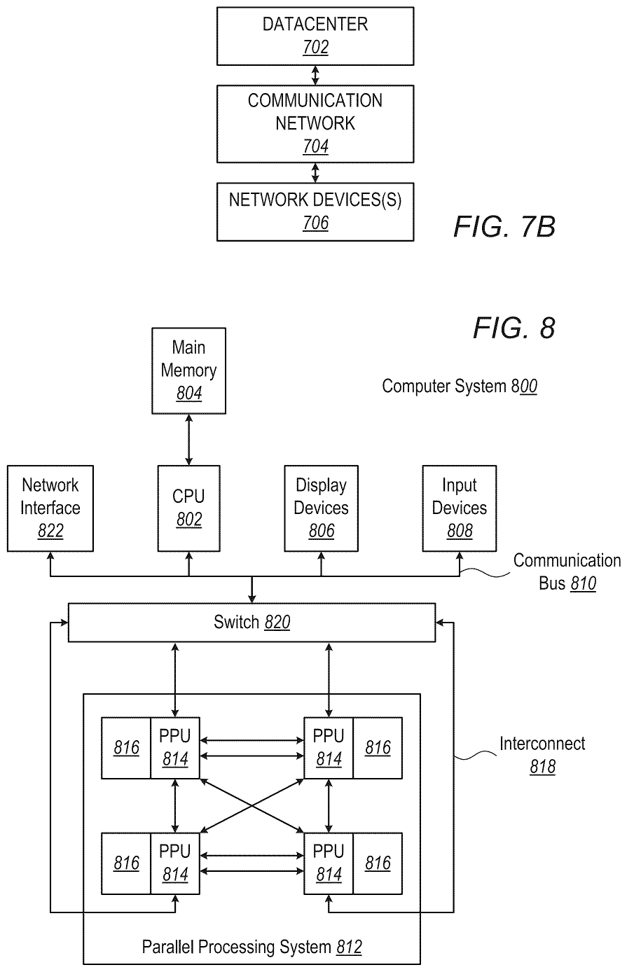

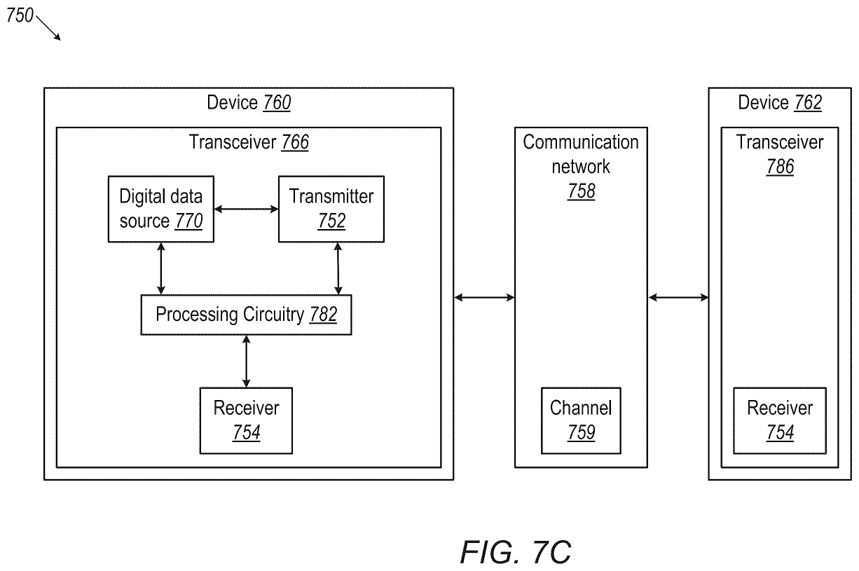

The disclosed techniques may be used for the testing of components in various electronic systems, such as those illustrated in FIGS. 7 through 11 and described herein below.

FIGS. 7A and 7B are, respectively, a 3-D view and a block diagram of a data center architecture 700, in accordance with an embodiment that is disclosed herein. The data Center architecture 700 comprises Processors 702 collectively referred to as the Data Center), which communicate over a Communication Network 704, with Network Devices 706. In embodiments, one or more of Devices 706 may comprise a transceiver, comprising a transmitter, a receiver, a digital data source and processing circuitry.

In high-capacity datacenter networks, such as those illustrated in FIGS. 7A-7B, a communication network 704 may leverage optical transceivers that transmit and receive optical signals over optical fibers or other optical communication mediums in order to establish connection between devices in the data center 702.

In at least one example embodiment, the datacenter 702 corresponds to a collection of network devices, such as network switches (e.g., Ethernet switches, IP routers, multiservice platforms, various transmission network elements, legacy communication equipment, or in any other suitable communication system) connected with a collection of servers or compute nodes.

A switch fabric serves to transfer the data between the switch ports. A switch fabric comprises one or more interconnect circuits, which may be arranged in various switch fabric architectures, e.g., m*m crossbar, Banyan, Benes, Omega, Clos, multi-plane, STS, TST, shared memory, buffered crossbar, any other suitable blocking or non-blocking architecture, or any applicable mixed architecture thereof. A switch fabric is realized in typical embodiments by hardware, which may comprise Field-Programmable Gate Arrays (FPGAs) and/or Application-Specific Integrated (ASICs), and in some implementations also bus Circuits interconnects. The datacenter 702 may adhere to a networking topology (e.g., a hierarchal networking topology), such as a fat tree topology, a Slim Fly topology, a Dragonfly topology, and/or the like. The datacenter 702 routes traffic amongst the network switches and servers therein, and at least one layer of the topology in the datacenter 702 is coupled to a communication network 704 to allow networking traffic to flow between the datacenter 702 and a network device(s) 706.

The communication network 704 may communicably couple the datacenter 702 with network device(s) 706 and other external devices for data exchange and connectivity. Examples of the communication network 704 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like.

In one specific but non-limiting example, the communication network 704 is a network that enables data transmission between the Data Center and the Device 706 using data signals (e.g., digital, optical, wireless signals). In embodiments, Device 706 may comprise two or more devices, that are connected to the Data Center through the Network 704.

Each type of network offers specific advantages tailored to different operational requirements. For instance, an IP network or Ethernet network may provide widespread compatibility and ease of integration, supporting various protocols and applications across the datacenter 702 and the network device(s) 706 (and/or external devices). An InfiniBand network may offer high throughput and low latency, ideal for HPC environments where rapid data transfer and minimal delay are required. Fibre Channel networks may be employed for their robust performance in storage area networks (SANS), ensuring fast and reliable access to storage resources. Cellular and wireless communication networks may be used to extend connectivity to remote or mobile devices for increased flexibility and accessibility.

Examples of the communication network 704 that may be used to connect the datacenter 700 and the network device(s) 706 include an Internet Protocol (IP) network, an Ethernet network, an InfiniBand (TB) network, a Fibre Channel network, the Internet, a cellular communication network, a wireless communication network, combinations thereof (e.g., Fibre Channel over Ethernet), variants thereof, and/or the like.

The network device(s) 706 may include a variety of computing devices capable of sending and receiving signals over the communication network 704. The network device(s) 706 can range from personal computing devices to complex server configurations. Examples include Personal Computers (PCS), laptops, tablets, smartphones, and servers. The network device(s) 706 may facilitate user interactions with the datacenter 702, allowing for data input, retrieval, and processing from remote locations. In addition to individual computing devices, the network device(s) 706 may also include collections of servers or additional datacenters. For instance, these could be other datacenters similar to or the same as datacenter 702. Such an interconnection may allow for the formation of a distributed computing environment for improved redundancy, load balancing, and disaster recovery capabilities. By linking multiple datacenters, the data center architecture 700 can leverage geographically dispersed resources, optimizing performance and ensuring high availability.

The one or more network devices 706 may include one or more of Personal Computer (PC), a laptop, a tablet, a smartphone, a server, a collection of servers, and/or any suitable computing device for sending and receiving signals over the communication network 704. In at least one example embodiment, the one or more network devices 706 correspond to another datacenter, similar to or the same as datacenter 702.

As noted above, the datacenter 702 and/or the network device(s) 706 may include storage devices and/or processing circuitry for carrying out computing tasks, for example, tasks associated with controlling the flow of data internally and/or over the communication network 704. Such processing circuitry may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory).

Although not explicitly shown, it should be appreciated that the datacenter 702 and network device(s) 706 may include one or more communication interfaces for facilitating wired and/or wireless communication between one another and other unillustrated elements of the data Center architecture 700. These communication interfaces may include a variety of technologies, including but not limited to Ethernet ports, fiber optic connections, Wi-Fi® transceivers, Bluetooth® modules, and cellular communication modules for integration and interoperability among the various components within the data Center architecture 700. Furthermore, it should be understood that the data center architecture 700 may include additional components and functionalities within the scope of the present disclosure. These components may comprise, without limitation, additional processing units, specialized accelerators (such as Tensor Processing Units or TPUs), enhanced security modules, and redundant power supplies. The inclusion of these elements is intended to ensure that the data center architecture 700 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the data center environment 100.

FIG. 7C is a block diagram that schematically illustrates an inter-transceiver communication system 750, in accordance with an embodiment that is disclosed herein. A First Device 760 communicates with a Second Device 762 over a Channel 759 in a Communication Network 758. The First Device 760 comprises a Transceiver 766, whereas the Second Device 762 comprises a Transceiver 786. The two transceivers 766, 786 connect a Receiver 754 of the Second Device 762 with a Receiver 754 of the First Device 760, over the Channel 759. Transceiver 766 may comprise, for example, a Transmitter 752, a Digital Data Source 770 and a Processing Circuit 782.

FIG. 8 illustrates a computer system 800, according to at least one embodiment. In at least one embodiment, computer system 800 is configured to implement various processes and methods described throughout this disclosure.

In at least one embodiment, computer system 800 comprises, without limitation, at least one central processing unit (“CPU”) 802 that is connected to a communication bus 810 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 800 includes, without limitation, a main memory 804 and control logic (e.g., implemented as hardware, software, or a combination thereof) and data are stored in main memory 804 which may take form of random access memory (“RAM”). In at least one embodiment, a network interface subsystem (“network interface”) 822 provides an interface to other computing devices and networks for receiving data from and transmitting data to other systems from computer system 800.

In at least one embodiment, computer system 800, in at least one embodiment, includes, without limitation, input devices 808, parallel processing system 812, and display devices 806 which can be implemented using a conventional cathode ray tube (“CRT”), liquid crystal display (“LCD”), light emitting diode (“LED”), plasma display, or other suitable display technologies. In at least one embodiment, user input is received from input devices 808 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 804 and/or secondary storage. Computer programs, if executed by one or more processors, enable system 800 to perform various functions in accordance with at least one embodiment. memory 804, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 802; parallel processing system 812; an integrated circuit capable of at least a portion of capabilities of both CPU 802; parallel processing system 812; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 800 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 812 includes, without limitation, a plurality of parallel processing units (“PPUs”) 814 and associated memories 816. In at least one embodiment, PPUs 814 are connected to a host processor or other peripheral devices via an interconnect 818 and a switch 820 or multiplexer. In at least one embodiment, parallel processing computational tasks across system 812 distributes PPUs 814 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 814, although such shared memory may incur performance penalties relative to use of local memory and registers resident to a PPU 814. In at least one embodiment, operation of PPUs 814 is synchronized through use of a command such as syncthreads( ) wherein all threads in a block (e.g., executed across multiple PPUs 814) to reach a certain point of execution of code before proceeding.

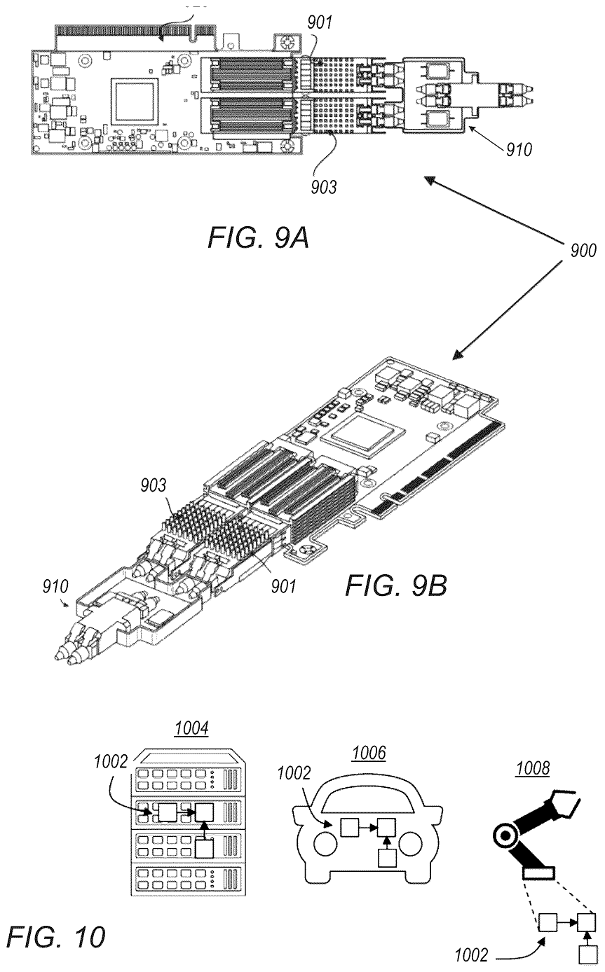

FIGS. 9A and 9B illustrate a top view and a perspective view, respectively, of a transceiver module operatively coupled to a network adapter, in the present example a Network Interface Controller (NIC) 900, in accordance with an embodiment of the disclosure. As shown in FIGS. 9A and 9B, the transceiver module may include a first optical module 901, a second optical module 903, an adapter 910, and a dual-port NIC 920 of a server. Both the first optical module 901 and the second optical module 903 may be dual-fiber transceivers that are configured for duplex communication that allows the source (e.g., server) to communicate with the target (e.g., leaf switch) in both directions. The adapter 910 may be a ganged physical component configured to link the first optical module 901 and the second optical module 903 for the purpose of transmitting and receiving data to and from the leaf switch.

In some embodiments, the adapter 910 may be configured to operate in two configurations, such as a first configuration and a second configuration. In one aspect, the first configuration may be a default configuration of operation, where the first optical module 901 may be operationally active. The second configuration may be a contingent configuration that is implemented when the first optical module 901 operationally fails. When such a failure is detected, the second optical module 903, which is otherwise operationally inactive or idle, may be engaged become operationally active and handle all network traffic that was initially handled by the first optical module 901. In some embodiments, the transceiver module 900 may be configured to operate in a leaf-spine architecture. A leaf-spine architecture is a data center network topology that may include two switching layers-a spine layer and a leaf layer. The leaf layer may include access switches (leaf switches) that aggregate traffic from servers and connect directly into the spine or network core. Spine switches interconnect all leaf switches in a full-mesh topology between access switches in the leaf layer and the servers from which the access switches aggregate traffic. As such, in one embodiment, to ensure reliable operation of downlinks, the transceiver module 900 may be configured to operate between the server and the leaf layer. In particular, as shown in FIGS. 9A and 9B, the adapter 910 may be operatively coupled to the first optical module 901 and the second optical module 903, while the first optical module 901 and the second optical module 903 may be operatively coupled to a dual-port NIC 920 of a server.

In embodiments, NIC 900 may comprise one or more processing circuits, as detailed above; the processing circuits may comprise FW, that is loaded according to the techniques described above.

FIG. 10 depicts exemplary scenarios for use of an optical a transceiver 1002 in accordance with some embodiments. An optical transceiver 1002 may be utilized in a computing system 1004 (e.g., in a server farm, or within a server computer system), a vehicle 1006 (e.g., a car, truck, train, or airplane), and a robot 1008 (or among robots in a factory), to name just a few examples. The optical transceiver 1002 may be particularly useful for high-speed communication in environments subject to high levels of electromagnetic interference (EMI).

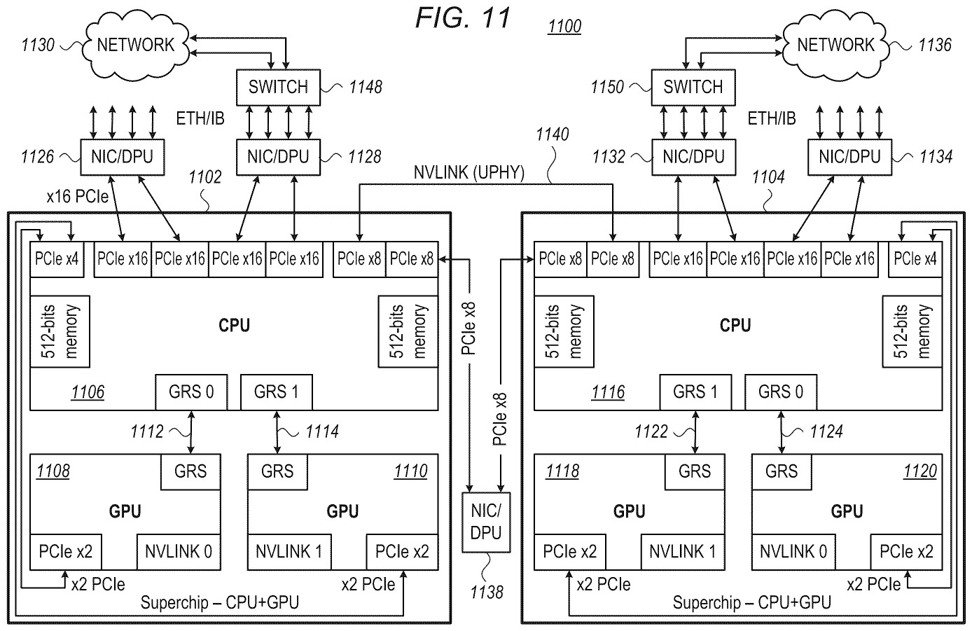

FIG. 11 is a block diagram that schematically illustrates a computing system 1100, e.g., a data center or a High-Performance Computing (HPC) cluster, in accordance with an embodiment that is described herein. System 1100 comprises a plurality of subsystems, e.g. multiple processing devices coupled to each other, multiple network devices, and multiple networks, according to at least one embodiment. Computing system 1100 is designed circuits (referred to as with multiple integrated processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1100 and to one or more external networks 1130, 1136. In the present example, system 1100 comprises a packet switch 1148 that connects NIC/DPU 1128 to network 1130, and a packet switch 1150 that connects NIC/DPU 1132 to network 1136.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1100 can include one or more CPUs and one or more GPUs.

FIG. 11 also demonstrates an example architecture of a multi-GPU architecture. As illustrated in the figure, computing system 1100 includes a processing device 1102 with a multi-GPU architecture. In particular, processing device 1102 may be a system-on-chip and includes multiple subsystems such as a CPU 1106, a GPU 1108, and a GPU 1110. CPU 1106 can be coupled to GPU 1108 via a die-to-die (D2D) or chip-to-chip (C2C) interconnect 1112, such as a Ground-Referenced Signaling interconnect (GRS interconnect). CPU 1106 can be coupled to GPU 1110 via a D2D or C2C interconnect 1114. CPU 1106 can also couple to GPU 1108 and GPU 1110 via PCIe interconnects.

CPU 1106 can be coupled to one or more NICs or DPUs, which are coupled to one or more networks. For example, as illustrated in FIG. 3, CPU 1106 is coupled to a first NIC/DPU 1126, which is coupled to a network 1130. CPU 1106 is also coupled to a second NIC/DPU 1128, which is coupled to network 1130 via switch 1148. NIC/DPU 1126 and NIC/DPU 1128 can be coupled to network 1130 over Ethernet (ETH), NVLINK or InfiniBand (IB) connections, for example.

Computing system 1100 also includes a processing device 1104 with a multi-GPU architecture. In particular, processing device 1104 includes multiple subsystems including a CPU 1116, a GPU 1118, and a GPU 1120. CPU 1116 can be coupled to GPU 1118 via an D2D or C2C interconnect 1122. CPU 1116 can be coupled to GPU 1120 via a D2D or C2C interconnect 1124. CPU 1116 can also couple to GPU 1118 and GPU 1120 via PCIe interconnects. CPU 1116 can be coupled to one or more NICs or DPUs, which are coupled to one or more networks. For example, as illustrated in FIG. 3, CPU 1116 is coupled to a first NIC/DPU 1132, which is coupled to a network 1136. CPU 1116 is also coupled to a second NIC/DPU 1134, which is coupled to network 1136 via switch 1150. NIC/DPU 1132 and NIC/DPU 1134 can be coupled to network 1136 over Ethernet (ETH), NVLINK or InfiniBand (IB) connections.

In at least one embodiment, processing device 1102 and processing device 1104 can communication with each other via a NIC/DPU 1138, such as over PCIe interconnects. Processing device 1102 and processing device 1104 can also communicate with each other over a high-bandwidth communication interconnects 1140, such as an NVLink interconnect or other high-speed interconnects. The packet switches in FIG. 11 may comprise, for example, Nvidia Quantum-2 switches. The NICs/DPUs in the figure may comprise, for example, Nvidia Bluefield DPUs.

Although the embodiments described herein mainly address temperature control in a testing procedure, the methods and devices described herein can also be used in other applications.

It will thus be appreciated that the embodiments described above are cited by way of example, and that the present disclosure is not limited to what has been particularly shown and described hereinabove. Rather, the scope of the present disclosure includes both combinations and sub-combinations of the various features described hereinabove, as well as variations and modifications thereof which would occur to persons skilled in the art upon reading the foregoing description and which are not disclosed in the prior art.

1. A testing temperature control system, comprising:
a Controlled-Temperature Device (CTD) Temperature Sensor, to send CTD-temperature data indicative of a temperature of a CTD in which a Device Under Test (DUT) is mounted;
a DUT-Temperature Control Circuit, to send a temperature control signal responsively to DUT-temperature data, the DUT temperature data being received from the DUT and indicative of a temperature of the DUT; and
a CTD Temperature Control Circuit, to control the temperature of the CTD responsively to the temperature control signal and to the CTD-temperature data.

2. The testing temperature control system according to claim 1, wherein the CTD Temperature Control Circuit is to control the temperature of the CTD responsively to a preset Proportional-Integral-Derivative (PID) function.

3. The testing temperature control system according to claim 1, wherein the DUT-Temperature Control Circuit is to send the temperature control signal responsively to a Process Value (PV) temperature setting input.

4. The testing temperature control system according to claim 1, wherein the DUT is to send the DUT-temperature data over a shared bus, and wherein the testing temperature control system further comprises arbitration circuitry to arbitrate the shared bus between the DUT-temperature data and testing control data.

5. The testing temperature control system according to claim 4, wherein the shared bus is an Inter-Integrated-Circuit (I2C) bus.

6. The testing temperature control system according to claim 1, wherein the DUT comprises a communication switch.

7. The testing temperature control system according to claim 1, wherein the DUT comprises a communication transceiver.

8. The testing temperature control system according to claim 1, further comprising a thermocouple device to send the CTD-temperature data.

9. A testing temperature control system, comprising:
a temperature setting device, to set a temperature of a Device Under Test (DUT);
a temperature control circuit, to receive from the DUT, over a shared bus, DUT-temperature data indicative of the temperature of the DUT as measured by the DUT, and to control the temperature setting device responsively to the DUT-temperature data; and
arbitration circuitry to arbitrate the shared bus between the DUT-temperature data and testing control data.

10. A method for controlling a temperature of a Device-Under-Test (DUT), the method comprising:
using a Controlled-Temperature Device (CTD) Temperature Sensor, sending CTD-temperature data indicative of a temperature of a CTD in which the DUT is mounted;
using a DUT-Temperature Control Circuit, sending a temperature control signal responsively to DUT-temperature data, the DUT temperature data being received from the DUT and indicative of a temperature of the DUT; and
using a CTD Temperature Control Circuit, controlling the temperature of the CTD responsively to the temperature control signal and to the CTD-temperature data.

11. The method according to claim 10, wherein controlling the temperature of the CTD is performed responsively to a preset Proportional-Integral-Derivative (PID) function.

12. The method according to claim 10, wherein sending the temperature control signal is performed responsively to a Process Value (PV) temperature setting input.

13. The method according to claim 10, wherein sending the DUT-temperature data is performed over a shared bus, and comprising arbitrating the shared bus between the DUT-temperature data and testing control data.

14. The method according to claim 13, wherein the shared bus is an Inter-Integrated-Circuit (I2C) bus.

15. The method according to claim 10, wherein the DUT comprises a communication switch.

16. The method according to claim 10, wherein the DUT comprises a communication transceiver.

17. The method according to claim 10, further comprising sending the CTD-temperature data by a thermocouple device.
